(19) United States
(12) Patent Application Publication
(10) Pub. No.: US 2007/0012940 A1
(43) Pub. Date: Jan. 18, 2007

(54) Wavelength-convertible light emitting diode package

(75) Inventors: Hyo Won Suh, Suncheon (KR); Hee Seok Park, Suwon (KR); Masayoshi Koike, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/484,758

(22) Filed: Jul. 12, 2006

(30) Foreign Application Priority Data
Jul. 14, 2005 (KR) 10-2005-0063532

(51) Int. Cl. H01L 33/00

(52) U.S. Cl. 257/99

(57) ABSTRACT

The invention relates to a wavelength-convertible LED package including a package substrate having a lead frame, and an LED mounted on the package substrate and electrically connected to the lead frame. The wavelength-convertible LED package also includes a low refractive index region surrounding the LED, having a first refractive index, and a high refractive index layer formed on the low refractive index region, having a rough pattern on an upper surface thereof and a second refractive index higher than the first refractive index. The wavelength-convertible LED package further includes a resin part containing phosphor for converting the wavelength of light emitted from the LED, having a third refractive index lower than the second refractive index.

### CLAIM OF PRIORITY

This application claims the benefit of Korean Patent Application No. 2005-63532 filed on Jul. 14, 2005, in the Korean Intellectual Property Office, the disclosure of which is incorporated herein by reference.

### BACKGROUND OF THE INVENTION

1. Field of the Invention

The present invention relates to a wavelength-convertible light emitting diode (LED) package, and more particularly, to a wavelength-convertible LED package with enhanced light extraction efficiency by adjusting the direction of photons scattered by phosphor particles.

2. Description of the Related Art

In general, a wavelength-convertible light emitting diode (LED) refers to a light source that uses phosphor powder to convert its own peculiar wavelength of emission color, thereby obtaining a desired emission color. In particular, there have been active researches to develop a wavelength-convertible LED for producing white color, which can be used as a high-output, high-efficiency light source that can substitute for the backlight of a display device.

FIG. 1 is a sectional view illustrating a white LED package 10 manufactured according to a conventional method.

Referring to FIG. 1, the white LED package 10 includes a package substrate 11, a blue light emitting device 15 mounted on the package substrate 11, and a transparent resin part 18 containing phosphor particles 19 such as TAG or YAG. The package substrate 11 includes a lower package substrate 11a with lead frames 12a and 12b formed thereon and an upper package substrate 11b having a sloped inner sidewall. Both electrodes (not shown) of the LED 6 are connected to upper ends of the lead frames 12a and 12b by wires.

The wavelength light emitted from the blue light emitting device 15 is converted in part into yellow light. The converted yellow light is combined with the remaining blue light to emit white light.

However, while being excited by the phosphor particles 19, a considerable number of photons scattered by the phosphor particles 19 are not emitted effectively to the outside, but rather absorbed by the resin part 18 or the light emitting device 15.

FIG. 2 is a schematic view illustrating such a problem of lowered light extraction efficiency, based on a supposition that the phosphor particles have circular shapes.

Referring to FIG. 2, light emitted from the LED is excited at the phosphor particles and can be scattered omnidirectionally from an entire surface of the particle. Among the scattered light, the light A scattered from the upper hemispheric surface of the particle above the dotted line is effectively extracted, but the light B below the dotted line propagates inside the package and absorbed into other parts, eventually being converted into heat and extinct.

According to publications, J. Light Vis. Environ. 27(2), 70, 2003 by K. Yamada et al. and Phys. stat. sol. (a) 202(6), R60 by N. Narendran et al., only 40% of the white photons excited by the phosphor can effectively be emitted, and the rest 60% of light propagates inside the package to eventually be extinct.

As discussed above, the wavelength-convertible LED package has a serious problem of poor light extraction efficiency due to the phosphor particles. Therefore, there has been a demand in the field for a wavelength-convertible LED package with a new optical structure by which the photons scattered by the phosphor particles propagate in an adjusted, effective direction.

### SUMMARY OF THE INVENTION

The present invention has been made to solve the foregoing problems of the prior art and therefore an object of certain embodiments of the present invention is to provide a wavelength-convertible light emitting diode (LED) package having a phosphor-containing resin part above an optical structure which utilizes different refractive indices and a rough pattern to effectively extract light that is scattered by phosphor particles to propagate inwardly.

According to an aspect of the invention for realizing the object, there is provided a wavelength-convertible light emitting diode package including: a package substrate having a lead frame; a light emitting device mounted on the package substrate to be electrically connected to the lead frame; a low refractive index region surrounding the light emitting device, and having a first refractive index; a high refractive index layer formed on the low refractive index region, the high refractive index layer having a rough pattern formed on an upper surface thereof and a second refractive index higher than the first refractive index; and a resin part formed on the high refractive index layer, the resin part containing phosphor for converting the wavelength of light emitted from the light emitting device and having a third refractive index lower than the second refractive index.

The low refractive index region may be an empty space, in which case, the region is filled by atmosphere and the first refractive index is about 1. Alternatively, the low refractive index region is filled with transparent resin. In this case, the transparent resin may be epoxy resin, silicone resin or mixture thereof.

The high refractive index layer can have various structures. It may be a transparent resin part having a high refractive index on the average. The rough pattern can be formed by a molding process or an additional etching process. According to an embodiment, the high refractive index layer may be made of transparent resin with high refractive index particles mixed therein. In that case, the high refractive index particle is made of one selected from a group consisting of GaP, Si, TiO₂, SrTiO₃, SiC, cubic or amorphous carbon, carbon nanotube, AlGaInP, AlGaAs, SiN, SiON, ITO, SiGe, AlN, GaN and mixtures thereof.

According to another embodiment, the high refractive index layer may be made of only high refractive index particles, and the shape of the rough pattern is determined by the shape of the high refractive index particles disposed on an upper part of the high refractive index layer.

The high refractive index layer has such a high refractive index that the photon scattered at the phosphor particle is totally reflected at the interface between the low refractive index region and the high refractive index layer, and preferably, has a refractive index of at least 1.8.

The high refractive index layer adopted in the invention has a rough pattern on an upper surface thereof to facilitate light extraction into the phosphor-containing resin part having a relatively low refractive index. Preferably, convexes of the rough pattern has a pitch of about 0.001 to 500 μm. In addition, in case when the refractive index difference is too large between the high refractive index layer and the phosphor-containing resin part, the rough pattern is limited in facilitating light extraction, and thus it is preferable that the high refractive index layer has a refractive index of up to 10.

The present invention can be applied to various forms of package structures. For example, the package substrate includes a lower package substrate with a lead frame formed thereon and an upper package substrate having a cavity with an outwardly sloped inner sidewall. In this case, the cavity is provided as a mounting area for the light emitting diode.

The wavelength-convertible light emitting diode package may further have an anti-reflective layer which is formed on a lower surface of the high refractive index layer, having anti-reflectivity in the wavelength of light emitted from the light emitting device, in order to facilitate light extraction of light generated from the light emitting device into the high refractive index layer.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a sectional view illustrating a conventional wavelength-convertible LED package;

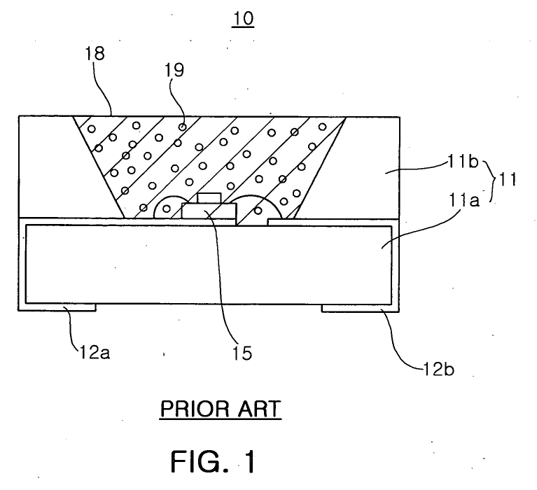

FIG. 2 is a schematic view illustrating emission directions of wavelength light converted by a phosphor particle;

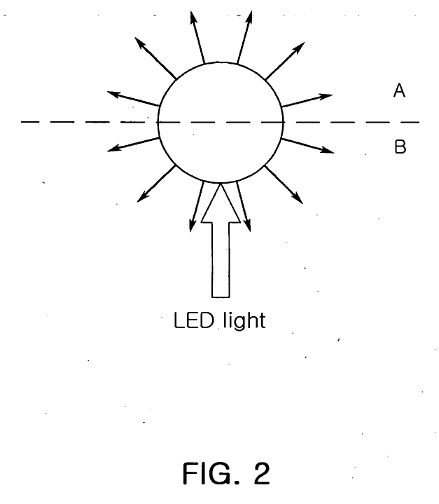

FIG. 3 is a sectional view illustrating a wavelength-convertible LED package according to an embodiment of the present invention;

FIG. 4 is a schematic view illustrating light extraction mechanism in the LED package shown in FIG. 3;

FIGS. 5(a) and 5(b) are sectional views illustrating a wavelength-convertible LED package according to another embodiment of the present invention; and

FIG. 6 is a sectional view illustrating a wavelength-convertible LED package according to further another embodiment of the present invention.

### DETAILED DESCRIPTION OF THE PREFERRED EMBODIMENT

Preferred embodiments of the present invention will now be described in detail with reference to the accompanying drawings.

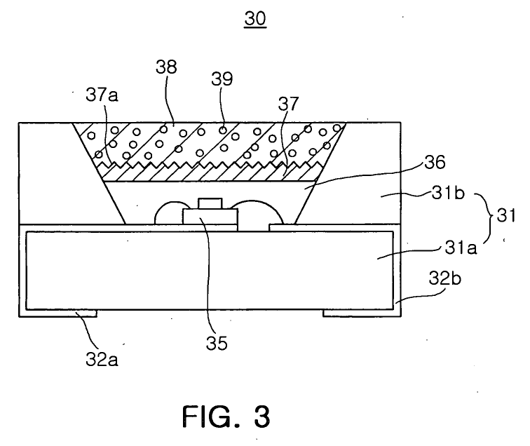

FIG. 3 is a sectional view illustrating a wavelength-convertible LED package according to an embodiment of the present invention.

Referring to FIG. 3, the LED package 30 includes a package substrate 31, and a light emitting device 35 mounted on the package substrate 31. The package substrate 31 can be divided into a lower package substrate 31a with two lead frames 32a and 32b, and an upper package substrate 31b having a cavity therein. The light emitting device 35 is mounted in the cavity. Both electrodes (not shown) of the light emitting device 35 are connected to upper ends of the lead frames 32a and 32b by wires.

A low refractive index region 36 is provided to surround the light emitting device 35. The low refractive index region 36 can be an empty space but can also be filled with transparent resin having a relatively low refractive index. In case when the low refractive index region 36 is an empty space, it has a refractive index (n=1) similar to that of the atmosphere. In case when the low refractive index region 36 is made of transparent resin, typical epoxy, silicone or mixture thereof can be used. In that case, the low refractive index region 36 may have a refractive index of about 1.7.

A high refractive index layer 37 is formed above the low refractive index region 36. The high refractive index layer 37 has a refractive index higher than that of the low refractive index region 36, and has a rough pattern 37a formed on an upper surface thereof. In addition, a resin part 38 is formed above the high refractive index layer 37. The resin part 38 contains phosphor 39 for converting the wavelength of light emitted from the light emitting device 35. The phosphor-containing resin part 38 has a lower refractive index than the high refractive index layer 37.

The high refractive index layer 37 may be made of resin having a high refractive index or made of a typical transparent resin layer containing high refractive index particles. In the latter case, the high refractive index particles may be made of one selected from a group consisting of GaP, Si, TiO₂, SrTiO₃, SiC, cubic or amorphous carbon, carbon nanotube, AlGaInP, AlGaAs, SiN, SiON, ITO, SiGe, AlN, GaN and mixtures thereof.

The high refractive index layer 37 has such a high refractive index that the photons scattered at the phosphor particles are totally reflected at the interface between the high refractive index layer 37 and the low refractive index region 36. It is preferable that the high refractive index layer 37 is formed to have a refractive index of at least 1.8. However, in case of forming the low refractive index region 36 with resin having a specific refractive index, the high refractive index layer 37 can be formed with material having a higher refractive index than the resin of the low refractive index region 36 so that there is a sufficient refractive index difference between the high refractive index layer 37 and the low refractive index region 36.

Although the critical angle for light extraction is somewhat small at the interface between the phosphor-containing resin part 38 and the high refractive index layer 37, the rough pattern 37a formed on the high refractive index layer 37 facilitates light extraction into the phosphor-containing resin part 38. Preferably, convexes of the rough pattern 37a may have a pitch of about 0.001 to 500 μm. In case when the refractive index difference is too large between the high refractive index layer 37 and the phosphor-containing resin part 38, the rough pattern 37a may not be effective for sufficient light extraction. Therefore, it is preferable that the high refractive index layer 37 has a refractive index of 10 or lower.

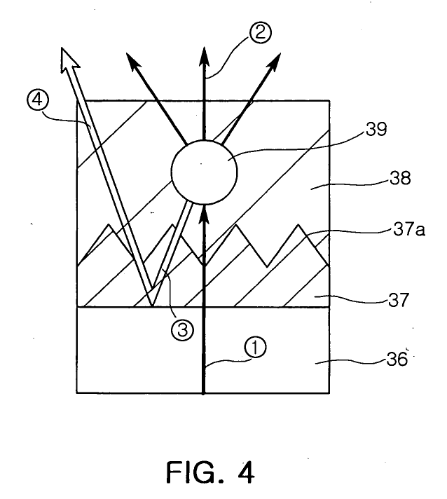

FIG. 4 is a schematic view illustrating light extraction mechanism of the LED package shown in FIG. 3.

Referring to FIGS. 3 and 4, the light \hat{1} emitted from the light emitting device 35 passes through the low refractive index region 36 and the high refractive index layer 37 to reach the phosphor-containing resin part 38. Typically, the low refractive index region 36 has a refractive index lower than the nitride constituting the light emitting device 35, but since a rough pattern (not shown) is formed on a surface of the LED, light emitted from the light emitting device 35 can effectively be extracted into the low refractive index region 36. Moreover, the light can be effectively extracted from the low refractive index region 36 into the high refractive index layer 37 because in this case, light is propagating from the low refractive index material to the high refractive index material. The phosphor-containing resin part has a lower refractive index than the high refractive index layer, thus having a limited critical angle for light extraction, but light can still be effectively extracted due to the rough pattern formed on an upper surface of the high refractive index layer.

The emission light \textcircled{1} of the LED collides into the phosphor particle 39, producing excited light, and a portion \textcircled{2} of the excited light can be extracted into a desired direction, i.e., the upper part of the package. On the other hand, other portion \textcircled{3} of the excited light is bound inward of the package to propagate from the phosphor-containing resin part 38 to the high refractive index layer 37. Since the phosphor-containing resin part 38 has a lower refractive index than the high refractive index layer 37, the light \textcircled{3} bound inward of the package can enter the high refractive index layer 37 with almost no loss. Most of the light \textcircled{3} that enters the high refractive index layer 37 is totally reflected by high refractive index difference at the interface between the low refractive index region 36 and the high refractive index layer 37. The totally reflected light \textcircled{4} propagates to the upper part of the high refractive index layer 37, and passes through the interface between the high refractive index layer 37 and the phosphor-containing resin part 38 to be extracted into a desired direction. As explained herein above, although the critical angle for light extraction is limited at the interface between the high refractive index layer 37 and the phosphor-containing resin part 38, the rough pattern 37a formed on an upper surface of the high refractive index layer 37 facilitates light extraction.

Therefore, the light \textcircled{3} that is scattered by the phosphor particles 39 to propagate inside the package can effectively be totally reflected in a desired upward direction by the high refractive index layer 37 with the rough patterned formed thereon and the low refractive index region 36.

The present invention adopts an optical structure in which a resin part containing phosphor particles is disposed above an optical structure with a high refractive index layer having a rough pattern and a low refractive index region. Thus, light scattered omni directionally at the phosphor particles can be adjusted to propagate upward, thereby improving light extraction efficiency.

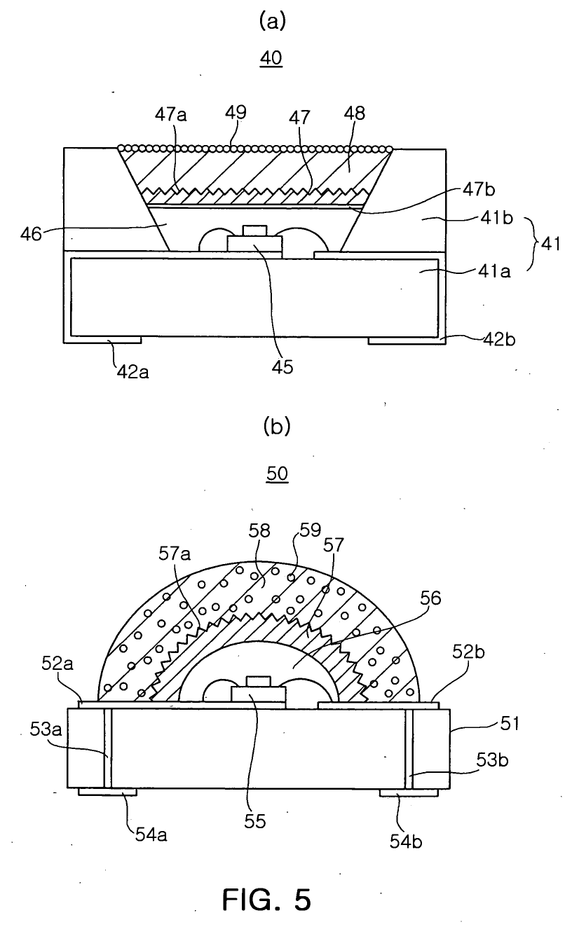

The present invention can be modified in various forms while maintaining distinctive constituents described above. FIGS. 5(a) and 5(b) are sectional views illustrating wavelength-convertible LED packages according to another embodiment of the invention. FIG. 5(a) illustrates a structure with an improved phosphor-containing resin part, and FIG. 5(b) illustrates a structure with a modified package substrate.

The LED package 40 shown in FIG. 5(a) includes a package substrate 41 and a light emitting device 45 mounted on the package substrate 41, similar to the LED package shown in FIG. 3. The package substrate 41 is composed of a lower package substrate 41a with two lead frames 42a and 42b formed thereon and an upper package substrate 41b having a cavity therein. Both electrodes (not shown) of the light emitting device 45 are connected respectively to the lead frames 42a and 42b by wires.

A low refractive index region 46 is provided to surround the light emitting device 45. The low refractive index region 46 can be an empty space or can be filled with epoxy or silicone resin having a relatively low refractive index. Alternatively, the low refractive index region 46 can be formed as an empty space while a lens (not shown) made of resin of low refractive index can be disposed to surround the light emitting device 45 in the empty space.

A high refractive index layer 47 is formed above the low refractive index region 46. The high refractive index layer 47 has a higher refractive index than the low refractive index region 46, and has a rough pattern 47a formed on an upper surface thereof. The rough pattern 47a formed on the high refractive index layer 47 can facilitate light extraction into a phosphor-containing resin part 48 which has a relatively low refractive index. Preferably, convexes of the rough pattern 47a have a pitch of about 0.001 to 500 μm.

According to this embodiment, an anti-reflective layer 47b can additionally be formed on a lower surface of the high refractive index layer 47, i.e., the interface between the high refractive index layer 47 and the low refractive index region 46. The anti-reflective layer 47b is made of material having anti-reflectivity in the wavelength band of the light emitting device 45, and can facilitate propagation of light emitted from the light emitting device 45 to the high refractive index layer 47.

A resin part 48 containing phosphor 49 is formed above the high refractive index layer 47 to convert the wavelength of light emitted from the light emitting device 45. The phosphor-containing resin layer 48 has a lower refractive index than the high refractive index layer 47.

In this embodiment, the phosphor-containing resin part 48 is formed by a typical method in which a transparent resin is formed and phosphor 49 is dispersed on an upper surface thereof. Similar to other embodiments, the layer made of phosphor particles 49 is disposed above an optical structure composed of a high refractive index layer 47 and a low refractive index region 46. Thus, improved light extraction efficiency according to the present invention is also expected from this embodiment.

In addition, the high refractive index layer 47 can be made of resin having a high refractive index or typical transparent resin containing high refractive index particles. It is preferable that the high refractive index layer 47 has a refractive index of at least 1.8 to allow total reflection of the photons scattered at the phosphor particles 49 at the interface between the high refractive index layer 47 and the low refractive index region 46, and up to 10 to facilitate light extraction into the phosphor-containing rein part 48.

According to this embodiment, in case of forming the low refractive index region 46 with epoxy or silicone resin, the high refractive index layer 47 and the phosphor-containing resin part 48 can be formed by applying and curing continuously, which however does not limit the manufacturing process of the package of the present invention. The rough pattern 47a formed on the high refractive index layer 47 can be formed by mechanical or chemical etching after the curing process or formed by a molding frame before the curing process.

The LED package illustrated in FIG. 5(b) includes a package substrate 51 and a light emitting device 55 mounted on the package substrate 51. The package substrate 51 includes two lead frames 52a and 52b on upper surfaces thereof, two connection pads 54a and 54b on lower surfaces thereof and conductive vias 53a and 53b connecting each of the lead frames with each of the connection pads, which however does not limit the present invention.

Similar to other embodiments, the LED package 50 includes a hemispheric low refractive index region 56 around a light emitting device 55, a high refractive index layer 57 formed to surround the low refractive index region 56, and a phosphor-containing resin part 58 formed above the high refractive index layer 57. The high refractive index layer 57 has a higher refractive index than the low refractive index region 56, and has a rough pattern 57a formed on an upper surface thereof. The phosphor-containing resin part 58 has a lower refractive index than the high refractive index layer 57.

According to this embodiment, the hemispheric low refractive index region 56 can be easily formed with transparent resin part using conventional molding processes such as transfer molding. In that case, other layers 57 and 58 can also be formed by similar molding processes. Alternatively, in case of providing the low refractive index region 56 as an empty space, the high refractive index layer 57 and/or the phosphor-containing resin part 58 can be manufactured into a desired shape in a separate molding process (e.g. transfer molding), and then attached to the package substrate 51. The high refractive index layer 57 and the phosphor-containing resin part 58 are exemplified by a hemispheric shape but can be formed in various shapes such as those having a rectangular or triangular cross-section.

The variety in shapes can be applied also to the structure in FIG. 5(a). In the embodiment shown in FIG. 5(a), the high refractive index layer 47 has a planar shape but can be modified to have a hemispheric shape similar to that in FIG. 5(b) or other shapes.

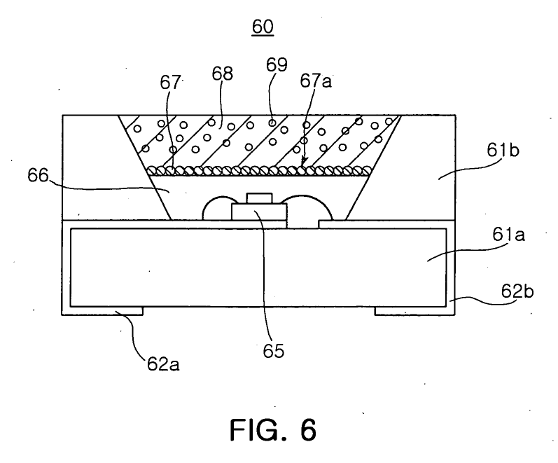

The high refractive index layer adopted in the invention can be formed in various shapes. In particular, the rough pattern does not have to be formed by typical molding or etching processes but can be formed only by the peculiar shape of high refractive index particles, which is illustrated in FIG. 6.

Referring to FIG. 6, similar to the embodiment shown in FIG. 3, the LED package 60 includes a package substrate 61 and a light emitting device 65 mounted on the package substrate 61. The package substrate 61 can be composed of a lower package substrate 61a with two lead frames 62a and 62b formed thereon and an upper package substrate 61b with a cavity therein.

A light emitting device 65 is mounted in the cavity. Both electrodes (not shown) of the light emitting device 65 are connected respectively to upper ends of the lead frames 62a and 62b by wires. A low refractive index region 66 is provided to surround the light emitting device 65.

The low refractive index region 66 can be an empty space or can be filled with transparent resin having relatively low refractive index. In case when the low refractive index region 66 is an empty space, it has a refractive index (n=1) similar to that of the atmosphere. In addition, in case when the low refractive index region 66 is formed with transparent resin, typical epoxy, silicone or mixture thereof can be used. In that case, the low refractive index region 66 can have a refractive index of about 1.7.

A high refractive index layer 67 is formed above the low refractive index region 66. The high refractive index layer 67 is made of high refractive index particles having a refractive index higher than the low refractive index region 66, and a rough pattern 67a thereon is formed with the particles. Therefore, the shape or pitch of the rough pattern 67a is determined by the diameter or shapes of the high refractive index particles. The high refractive index particles may be made of one selected from a group consisting of GaP, Si, TiO₂, SrTiO₃, SiC, cubic or amorphous carbon, carbon nanotube, AlGaInP, AlGaAs, SiN, SiON, ITO, SiGe, AlN, GaN and mixtures thereof.

The high refractive index layer 67 can be formed in a separate process as a film structure with the high refractive index particles disposed at least on the upper surface thereof, and then can be placed in the cavity. Alternatively, in case when the low refractive index region 66 is formed with a specific resin, the high refractive index particles can be densely dispersed on the upper surface of the resin to form the high refractive index layer 67.

A resin part 68 containing phosphor 69 is formed above the high refractive index layer 67 to convert the wavelength of light emitted from the light emitting device 65. The phosphor-containing resin part 68 has a lower refractive index than the high refractive index layer 67.

The rough pattern 67a formed on the high refractive index layer 67 facilitates light extraction into the phosphor-containing resin part 68 which has a relatively low refractive index. In case when the refractive index difference is too large between the high refractive index layer 67 and the phosphor-containing resin part 68, the rough pattern 67a may not be effective for sufficient light extraction. Therefore, it is preferable that the high refractive index layer 67 has a refractive index of up to 10.

According to the present invention as set forth above, a phosphor-containing resin part is disposed above a new optical structure utilizing different refractive indices and a rough pattern, thereby effectively re-extract light, into a desired direction, which is scattered by phosphor particles and propagates inside the package. Consequently, the invention provides a wavelength-convertible LED having excellent light extraction efficiency.

While the present invention has been shown and described in connection with the preferred embodiments, it will be apparent to those skilled in the art that modifications and variations can be made without departing from the spirit and scope of the invention as defined by the appended claims.

What is claimed is:

1. A wavelength-convertible light emitting diode package comprising:
a package substrate having a lead frame;
a light emitting device mounted on the package substrate to be electrically connected to the lead frame;
a low refractive index region surrounding the light emitting device, and having a first refractive index;
a high refractive index layer formed on the low refractive index region, the high refractive index layer having a rough pattern formed on an upper surface thereof and a second refractive index higher than the first refractive index; and
a resin part formed on the high refractive index layer, the resin part containing phosphor for converting the wavelength of light emitted from the light emitting device and having a third refractive index lower than the second refractive index.

2. The wavelength-convertible light emitting diode package according to claim 1, wherein the low refractive index region is an empty space, and the first refractive index is about 1.

3. The wavelength-convertible light emitting diode package according to claim 1, wherein the low refractive index region is filled with transparent resin.

4. The wavelength-convertible light emitting diode package according to claim 3, wherein the transparent resin comprises epoxy resin, silicone resin or mixture thereof.

5. The wavelength-convertible light emitting diode package according to claim 1, wherein the high refractive index layer has a refractive index ranging from 1.8 to 10.

6. The wavelength-convertible light emitting diode package according to claim 1, wherein the high refractive index layer has convexes that have a pitch of about 0.001 to 500 μm.

7. The wavelength-convertible light emitting diode package according to claim 1, wherein the high refractive index layer is a transparent resin layer with high refractive index particles mixed therein, and comprises the rough pattern formed on a surface of the resin part.

8. The wavelength-convertible light emitting diode package according to claim 7, wherein the high refractive index particle is made of one selected from a group consisting of GaP, Si, TiO₂, SrTiO₃, SiC, cubic or amorphous carbon, carbon nanotube, AlGaInP, AlGaAs, SiN, SiON, ITO, SiGe, AlN, GaN and mixtures thereof.

9. The wavelength-convertible light emitting diode package according to claim 1, wherein the high refractive index layer is made of high refractive index particles, and the rough pattern is formed by the shape of the high refractive index particles disposed on an upper part of the high refractive index layer.

10. The wavelength-convertible light emitting diode package according to claim 9, wherein the high refractive index particle is made of one selected from a group consisting of GaP, Si, TiO₂, SrTiO₃, SiC, cubic or amorphous carbon, carbon nanotube, AlGaInP, AlGaAs, SiN, SiON, ITO, SiGe, AlN, GaN and mixtures thereof.

11. The wavelength-convertible light emitting diode package according to claim 1, wherein the package substrate comprises a lower package substrate with a lead frame formed thereon and an upper package substrate having a cavity with an outwardly sloped inner sidewall, and
the cavity is provided as a mounting area for the light emitting diode.

12. The wavelength-convertible light emitting diode package according to claim 1, further comprising an anti-reflective layer formed on a lower surface of the high refractive index layer, the anti-reflective layer having no reflectivity in the wavelength of light emitted from the light emitting device.
